(19) United States
(12) Patent Application Publication
(10) Pub. No.: US 2021/0358725 A1
(43) Pub. Date: Nov. 18, 2021

(54) SUBSTRATE SUPPORT ASSEMBLY, SUBSTRATE PROCESSING APPARATUS, AND SUBSTRATE PROCESSING METHOD

(71) Applicant: Tokyo Electron Limited, Tokyo (JP)

(72) Inventor: Kazuki OSHIMA, Miyagi (JP)

(21) Appl. No.: 17/236,165

(22) Filed: Apr. 21, 2021

(30) Foreign Application Priority Data
May 15, 2020 (JP) 2020-085832

(51) Int. Cl. H01J 37/32; H01L 21/67; H01L 21/683; H01L 21/687; H01L 21/3065

(52) U.S. Cl. CPC H01J 37/32724; H01L 21/67069; H01L 21/6833; H01L 21/68721; H01L 21/68757; H01J 2237/334; H01J 37/32642; H01J 37/3244; H01J 37/32082; H01J 2237/2007; H01L 21/3065

(57) ABSTRACT

A substrate support assembly for mounting a substrate is provided. The substrate support assembly includes: a substrate mounting section on which a substrate is to be placed; an edge ring mounting section; an edge ring mounted on the edge ring mounting section so as to surround the substrate; a dielectric member having a temperature dependent permittivity provided under the edge ring; and a temperature control member configured to adjust a temperature of the dielectric member. The dielectric member and the temperature control member are disposed apart from the edge ring.

### CROSS-REFERENCE TO RELATED APPLICATIONS

This patent application is based upon and claims priority to Japanese Patent Application No. 2020-085832 filed on May 15, 2020, the entire contents of which are incorporated herein by reference.

### TECHNICAL FIELD

The present disclosure relates to a substrate support assembly, a substrate processing apparatus, and a substrate processing method.

### BACKGROUND

It is known that consumption of a focus ring (edge ring) affects the substrate processing such as an edge shape (Patent Document 1, Patent Document 2, Patent Document 3, etc.).

### RELATED ART DOCUMENTS

### Patent Documents

[Patent Document 1] Japanese Laid-open Patent Application Publication No. 2007-258417
[Patent Document 2] Japanese Laid-open Patent Application Publication No. 2008-244274
[Patent Document 3] U.S. Patent Application Publication No. 2018/0366304

### SUMMARY

The present disclosure provides a technique for reducing the influence of consumption of the edge ring.

According to one aspect of the present disclosure, a substrate support assembly for mounting a substrate is provided. The substrate support assembly includes: a substrate mounting section on which a substrate is placed; an edge ring mounting section; an edge ring placed on the edge ring mounting section so as to surround the substrate; a dielectric member having a temperature dependent permittivity provided under the edge ring; and a temperature control member configured to adjust a temperature of the dielectric member. The dielectric member and the temperature control member are disposed apart from the edge ring.

### BRIEF DESCRIPTION OF THE DRAWINGS

FIG. 1 is a cross-sectional view illustrating the schematic configuration of a substrate processing apparatus according to a first embodiment;

FIG. 2 is an enlarged cross-sectional view illustrating the vicinity of an edge ring of the substrate processing apparatus according to the first embodiment;

FIG. 3 is a diagram illustrating the temperature characteristic of a dielectric member in the substrate processing apparatus according to the first embodiment;

FIGS. 4 to 6 are diagrams illustrating the electric field distribution around the edge ring of the substrate processing apparatus according to the first embodiment;

FIG. 7 is a flowchart of a permittivity adjustment process in the substrate processing apparatus according to the first embodiment;

FIG. 8 is an enlarged cross-sectional view illustrating the vicinity of an edge ring for a substrate processing apparatus according to a second embodiment; and

FIG. 9 is an enlarged cross-sectional view illustrating the vicinity of an edge ring for a substrate processing apparatus according to a third embodiment.

### DETAILED DESCRIPTION OF EMBODIMENTS

Hereinafter, embodiments for carrying out the present disclosure will be described with reference to the drawings. Note that in the present specification and drawings, the same reference symbol is given to elements having substantially identical features, and duplicate descriptions will be omitted. For ease of comprehension, the scale of each part in the drawings may differ from the actual scale. Directions such as parallel, rectangular, orthogonal, horizontal, perpendicular, vertical, and lateral are allowed to deviate as long as the effects of the embodiments are not compromised. The shape of a corner is not limited to a right angle, and may be rounded in an arch. Parallel, rectangular, orthogonal, horizontal, and vertical may include generally parallel, generally rectangular, generally orthogonal, generally horizontal, and generally vertical, respectively.

### First Embodiment

### <Overall Configuration of Substrate Processing Apparatus 1>

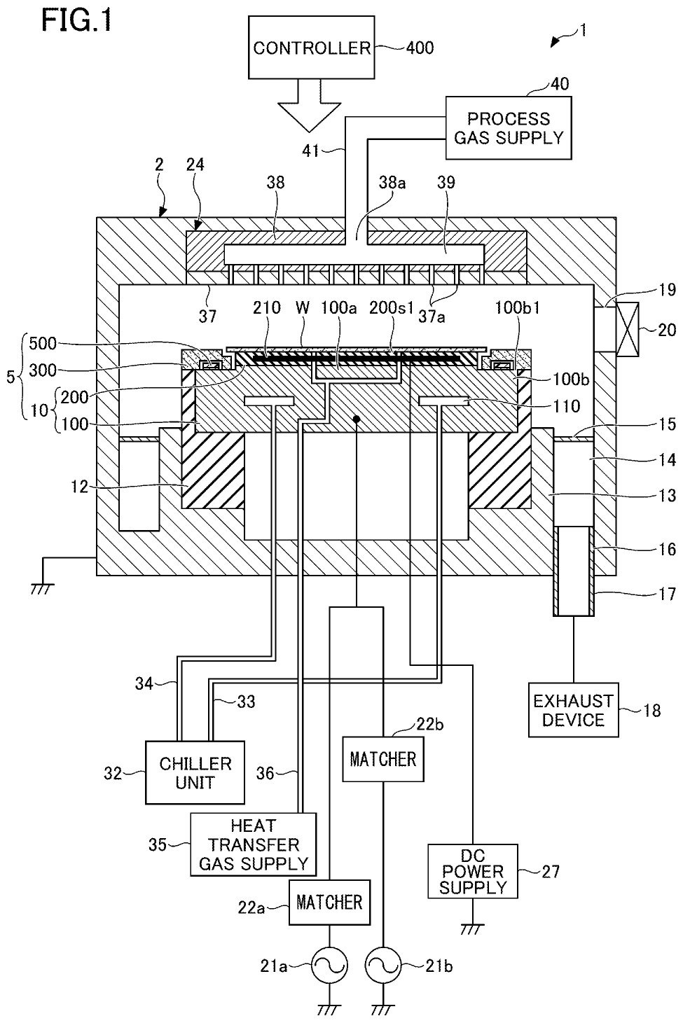

First, an example of the overall configuration of a substrate processing apparatus 1 will be described with reference to FIG. 1. FIG. 1 is a cross-sectional view illustrating the schematic configuration of the substrate processing apparatus 1 according to a first embodiment. In the first embodiment, a case in which the substrate processing apparatus 1 is a reactive ion etching (RIE) type substrate processing apparatus will be described. However, the substrate processing apparatus 1 may be a plasma etching apparatus, a plasma chemical vapor deposition (CVD) apparatus, or the like.

In FIG. 1, the substrate processing apparatus 1 includes a grounded cylindrical processing vessel 2, which is formed of metal, such as aluminum or stainless steel. A disc-shaped stage 10, on which a substrate W is placed, is disposed in the processing vessel 2. The stage 10 includes a base 100 and an electrostatic chuck 200. The base 100 serves as a bottom electrode. The base 100 is, for example, formed of aluminum. The base 100 is supported by a cylindrical support 13 extending vertically upward from the bottom of the processing vessel 2 via an insulating cylindrical support member 12. For example, the direction from the stage 10 toward the substrate W may be referred to as an upward direction, and the direction from the substrate W toward the stage 10 may be referred to as a downward direction.

An exhaust passage 14 is formed between the inner side wall of the processing vessel 2 and the cylindrical support 13, and an annular baffle plate 15 is arranged at the inlet or at a location partway along the exhaust passage 14. An exhaust port 16 is also provided at the bottom of the exhaust passage 14, and an exhaust device 18 is connected to the exhaust port 16 via an exhaust pipe 17. Here, the exhaust device 18 includes a dry pump and a vacuum pump to reduce the pressure in a processing space within the processing vessel 2 to a predetermined level. The exhaust pipe 17 also includes an automatic pressure control valve (hereinafter referred to as “APC”) which is a variable butterfly valve, and the APC automatically controls the pressure in the processing vessel 2. Further, a gate valve 20 for opening and closing a loading/unloading port 19 of the substrate W is mounted to the side wall of the processing vessel 2. The exhaust port 16 is an example of a gas exhaust port.

The base 100 is connected to a radio frequency (RF) power supply via a matcher. In the example of FIG. 1, a first radio frequency power supply 21a is connected to the base 100 via a matcher 22a. A second radio frequency power supply 21b is also connected to the base 100 via a matcher 22b. The first radio frequency power supply 21a supplies radio frequency power for plasma generation to the base 100 at a predetermined frequency (e.g., 40 MHz). The second radio frequency power supply 21b supplies radio frequency power for drawing ions to the base 100 at a predetermined frequency (e.g., 400 kHz) lower than the frequency of the first radio frequency power supply 21a.

A showerhead 24, which also serves as an upper electrode, is disposed on the ceiling of the processing vessel 2. Accordingly, two frequencies of radio frequency power are supplied to an area between the base 100 and the showerhead 24 from the first and second radio frequency power supplies 21a and 21b.

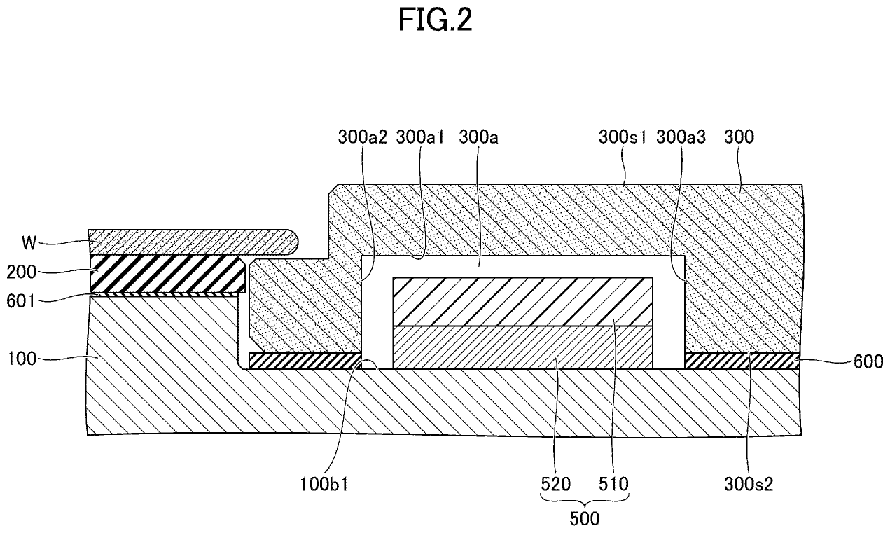

The base 100 has a disc-shaped central portion 100a and an annular outer peripheral portion 100b formed to surround the central portion 100a. The central portion 100a protrudes in the upward direction in the drawing, with respect to the outer peripheral portion 100b. The electrostatic chuck 200 is provided on the upper surface of the central portion 100a of the base 100 to attract the substrate W by electrostatic attracting force. The base 100 and the electrostatic chuck 200 are bonded and fixed via an adhesive layer 601 (see FIG. 2). The upper surface of the electrostatic chuck 200 is a substrate mounting surface 200s1 on which a substrate W is placed. The electrostatic chuck 200 is an example of a substrate mounting section.

The upper surface of the outer peripheral portion 100b of the base 100 is an edge ring mounting surface 100b1 on which an edge ring 300 is placed. The edge ring mounting surface 100b1 is configured such that the edge ring 300 is placed around the substrate mounting surface 200s1. That is, the edge ring 300 is disposed around the substrate W. The base 100 and the edge ring 300 are secured together via the adhesive layer 600 (see FIG. 2). The edge ring 300 is also referred to as a focus ring. The outer peripheral portion 100b is an example of an edge ring mounting section.

The electrostatic chuck 200 is formed by sandwiching a substrate attracting electrode plate 210 made of a conductive film between a pair of dielectric films. A direct-current (DC) power supply 27 is electrically connected to the substrate attracting electrode plate 210.

A permittivity adjuster 500 is provided between the base 100 and the edge ring 300, in other words, under the edge ring 300. Details of the permittivity adjuster 500 will be described below.

In addition, the combination of the stage 10, the edge ring 300, and the permittivity adjuster 500 may be referred to as a substrate support assembly 5.

The DC power supply 27 is capable of changing the level and polarity of DC voltage supplied. The DC power supply 27 applies DC voltage to the substrate attracting electrode plate 210 by control of a controller 400, which will be described below. The electrostatic chuck 200 generates electrostatic force, such as Coulomb force, by the voltage applied from the DC power supply 27 to the substrate attracting electrode plate 210, and draws and holds the substrate W to the electrostatic chuck 200 by the electrostatic force.

Inside the base 100, a flow passage 110 that extends, for example, in a circumferential direction, is provided. Refrigerant at a predetermined temperature, for example, cooling water, is supplied from a chiller unit 32 to the flow passage 110 through pipes 33 and 34, and the refrigerant circulates in the flow passage 110 to control the temperature of the substrate W on the electrostatic chuck 200 and the temperature of the edge ring 300, by the temperature of the refrigerant. The refrigerant is an example of a temperature adjusting medium (a temperature controlling medium) that is supplied to the flow passage 110 and circulates in the flow passage 110. The temperature controlling medium not only cools the base 100 and the substrate W, but may also heat them.

A heat transfer gas supply 35 is connected to the electrostatic chuck 200 via a gas supply line 36. The heat transfer gas supply 35 uses the gas supply line 36 to supply a heat transfer gas to the space sandwiched between the substrate mounting surface 200s1 of the electrostatic chuck 200 and the substrate W. As the heat transfer gas, a gas having heat conductivity, such as He gas, is preferably used. The heat transfer gas is supplied between the electrostatic chuck 200 and the substrate W to efficiently transfer heat from the plasma to the substrate W to the base 100.

The showerhead 24 provided at the ceiling includes an electrode plate 37 on the lower surface having multiple gas holes 37a and an electrode support 38 detachably supporting the electrode plate 37. A buffer chamber 39 is provided within the electrode support 38, and a process gas supply 40 is connected to a gas inlet 38a in communication with the buffer chamber 39 via a gas supply line 41. The gas inlet 38a is an example of a gas supply port.

Each component of the substrate processing apparatus 1 is connected to the controller 400. For example, the exhaust device 18, the first radio frequency power supply 21a, the second radio frequency power supply 21b, the matcher 22a, the matcher 22b, the DC power supply 27, the chiller unit 32, the permittivity adjuster 500 (temperature control member 520, see FIG. 2), the heat transfer gas supply 35, and the process gas supply 40 are connected to the controller 400. The controller 400 controls each of the components of the substrate processing apparatus 1.

The controller 400 includes a central processing unit (CPU) and a storage device such as a memory (not illustrated). The controller 400 performs desired processes in the substrate processing apparatus 1, by the CPU loading and executing a program and a process recipe stored in the storage device.

In the substrate processing apparatus 1, first, the gate valve 20 is opened, and a substrate W to be processed is loaded into the processing vessel 2 and placed on the electrostatic chuck 200. Then, in the substrate processing apparatus 1, the process gas supply 40 introduces a process gas (for example, a mixture of C₄F₃ gas, O₂ gas, and Ar gas) into the processing vessel 2 at a predetermined flow rate and flow rate ratio, and the pressure in the processing vessel 2 is set to a predetermined value by the exhaust device 18 or the like.

Further, in the substrate processing apparatus 1, the first and second radio frequency power supplies 21a and 21b respectively supply radio frequency power having different frequencies to the base 100. Also, in the substrate processing apparatus 1, DC voltage is applied to the substrate attracting electrode plate 210 of the electrostatic chuck 200 from the DC power supply 27, to cause the electrostatic chuck 200 to attract the substrate W. The process gas discharged from the showerhead 24 is formed into a plasma, and etching is applied to the substrate W by radicals and ions in the plasma.

### <Permittivity Adjuster 500>

Next, the permittivity adjuster 500 will be described. FIG. 2 is an enlarged cross-sectional view illustrating the vicinity of the edge ring 300 of the substrate processing apparatus 1 according to the first embodiment.

The edge ring 300 has a top surface 300s1 exposed to plasma and a bottom surface 300s2 mounted on the edge ring mounting surface 100b1, which is the side opposite to the top surface 300s1. The edge ring 300 is secured to the edge ring mounting surface 100b1 via the adhesive layer 600. At the bottom surface 300s2 of the edge ring 300, a recess 300a for accommodating the permittivity adjuster 500 is provided. The recess 300a is of an annular shape when the edge ring 300 is viewed from below. The top surface of the recess 300a is referred to as a ceiling surface 300a1, a side surface of the side surfaces of the recess 300a, which is located closer to the substrate W, is referred to as a side surface 300a2, and the other side surface of the recess 300a is referred to as a side surface 300a3. The recess 300a is an example of a first recess.

The permittivity adjuster 500 includes a dielectric member 510 and a temperature control member 520. The dielectric member 510 is placed on the top surface of the temperature control member 520. The dielectric member 510 and the temperature control member 520 are of an annular-shape when viewed from above. The edge ring 300 and the permittivity adjuster 500 are removably disposed.

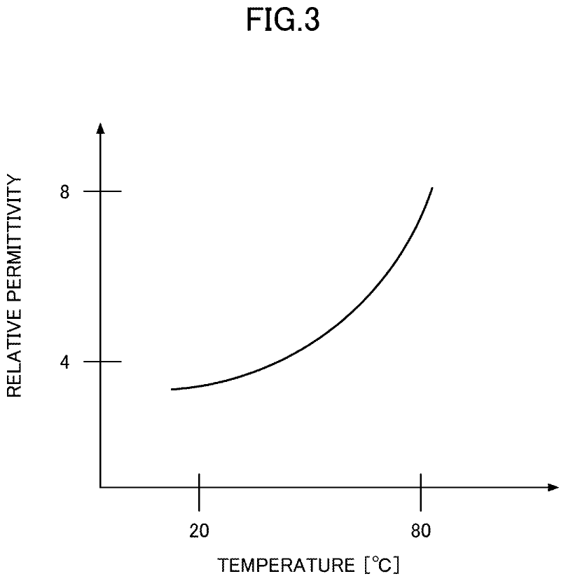

The permittivity of the dielectric member 510 is temperature dependent. The dielectric member 510 is made of, for example, polyamide, polyacetal, or a combination of polyamide and polyacetal. The temperature characteristics of the permittivity of the dielectric member 510 will be described. FIG. 3 is a diagram illustrating the temperature characteristic of the relative permittivity of the dielectric member 510 in the substrate processing apparatus 1 according to the first embodiment. The horizontal axis of FIG. 3 indicates temperature and the vertical axis indicates relative permittivity. FIG. 3 illustrates a case in which polyamide is used as a material of the dielectric member 510. For example, as the temperature of the dielectric member 510 rises, the relative permittivity of the dielectric member 510 also rises. Thus, by controlling the temperature of the dielectric member 510, the relative permittivity or the permittivity of the dielectric member 510 can be controlled.

The temperature control member 520 controls the temperature of the dielectric member 510. The temperature control member 520 is, for example, an electric heater. The temperature control member 520 may be formed of, for example, ceramic or aluminum. As the temperature control member 520 adjusts the temperature of the dielectric member 510, the permittivity of the dielectric member 510 can be controlled.

The permittivity adjuster 500 (dielectric member 510 and temperature control member 520) is disposed apart from the edge ring 300 so that the permittivity adjuster 500 does not contact the edge ring 300. According to the above-described configuration, when the processing space is depressurized to a predetermined degree of vacuum, the space between the permittivity adjuster 500 and the edge ring 300 is also depressurized, and the permittivity adjuster 500 is vacuum-insulated. Therefore, surface temperature change of the edge ring 300 due to heat transfer from the permittivity adjuster 500 is unlikely to occur, and thus the influence on the process conditions can be suppressed. Also, variation in permittivity of the dielectric member 510 can also be reduced because the dielectric member 510 is prevented from being heated by heat input from the plasma through the edge ring 300.

### <Adjustment of Electric Field Distribution by Permittivity Adjuster 500>

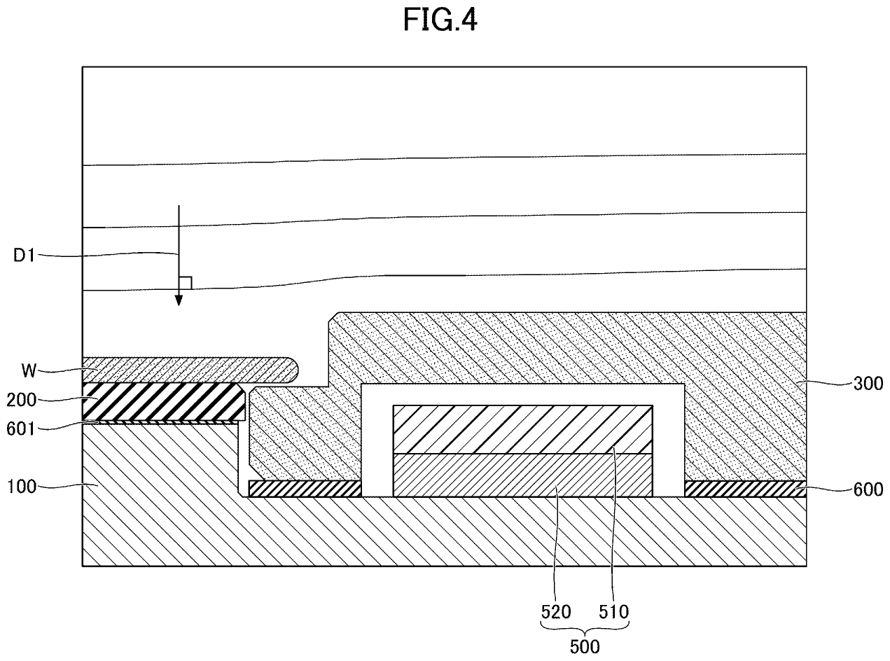

Next, results of changes in electric field distribution when the permittivity adjuster 500 is operated, which were obtained by simulation, are illustrated in FIGS. 4 to 6. FIGS. 4 to 6 are diagrams illustrating the electric field distribution around the edge ring 300 of the substrate processing apparatus 1 according to the first embodiment. In FIGS. 4 to 6, the electric field distribution is illustrated by equipotential lines.

First, a case in which the edge ring 300 is in an unused state (i.e., a state in which there is no wear) will be described. FIG. 4 is a result of simulation for an unused edge ring 300, in which the temperature of the dielectric member 510 was set to 20° C. and in which the relative permittivity of the dielectric member 510 was 4. The arrow D1 in FIG. 4 indicates an incident direction of ions near the edge of the substrate W. The unused edge ring 300 is optimized such that ions incident the substrate W perpendicularly. Accordingly, the etching profile becomes perpendicular at both the central region and the edge region of the substrate W, and there is no variation in quality.

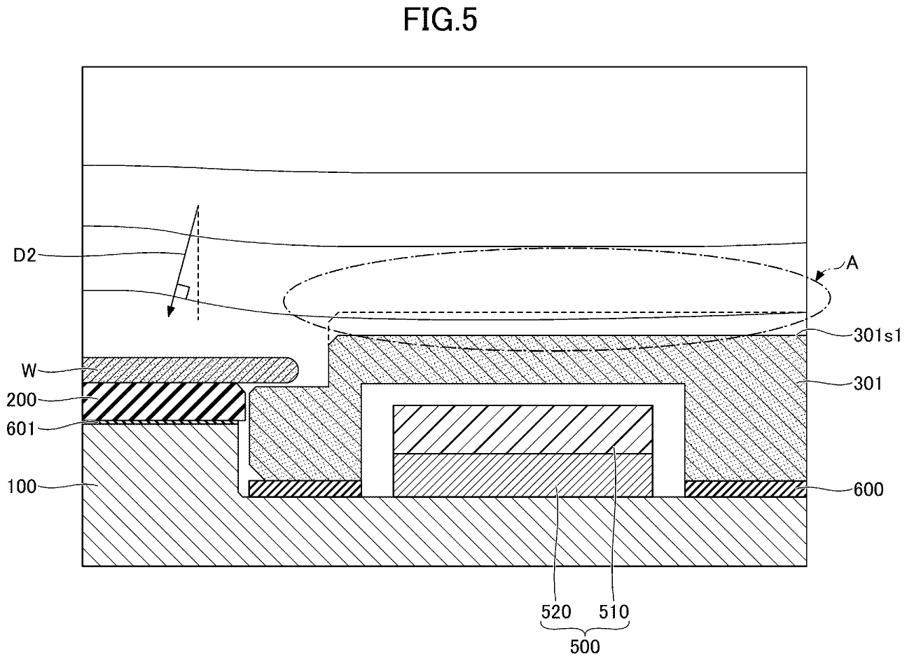

Next, a case in which the edge ring 300 is consumed by the substrate processing will be described. FIG. 5 is a result of simulation for the edge ring 300 that has been consumed as a result of using the edge ring 300 repeatedly, in which the temperature of the dielectric member 510 was set to 20° C. and in which the relative permittivity of the dielectric member 510 was 4. In the following description, the edge ring 300 in a consumed state may be referred to as an edge ring 301.

In FIG. 5, the dotted line above the edge ring 301 represents the shape of an unused edge ring 300. As the edge ring 300 is consumed from the state illustrated by the dotted line, the edge ring 301 becomes thinner than the unused edge ring 300. Therefore, the top surface 301s1 of the edge ring 301 becomes closer to the base 100 as compared to the top surface of the unused edge ring 300, and the electric field distribution in the region A above the edge ring 301 is shifted toward the base 100. As the electric field distribution is shifted toward the base 100, the incident direction of ions tilts at the edge region of the substrate W, as indicated by the arrow D2 tilted toward the substrate W.

As indicated by the arrow D2, when the incident direction of ions is inclined inward, from a direction perpendicular to the substrate W, the direction of etching also becomes inclined inward, from a direction perpendicular to the substrate W. Accordingly, although the etching profile remains perpendicular at the central region of the substrate W, the etching profile at the edge region becomes inclined inward. Accordingly, the etching profiles differ between the central region of the substrate W and the edge region of the substrate W, resulting in variation in quality.

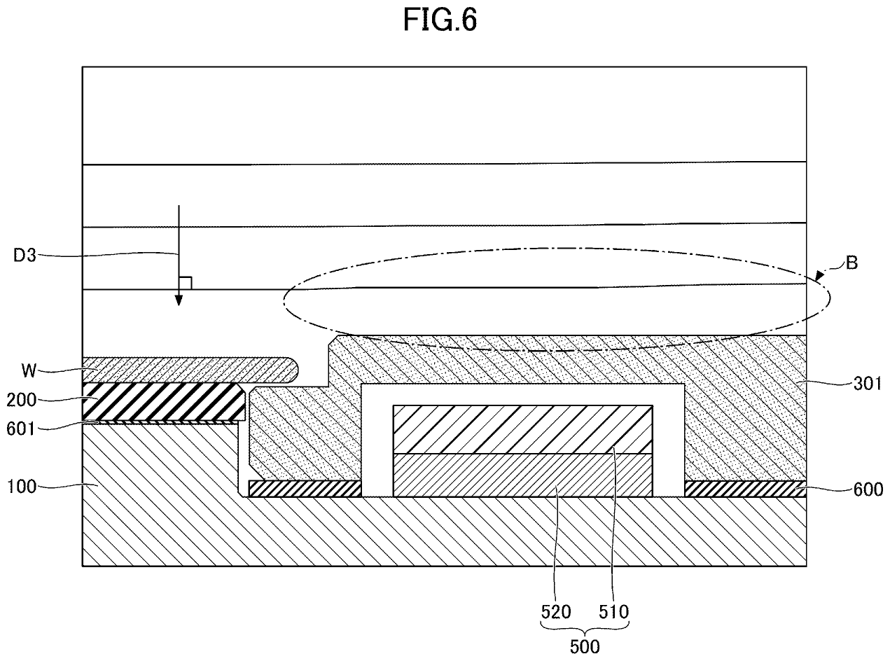

Next, a result of a case in which the electric field distribution was adjusted using the permittivity adjuster 500, with respect to the substrate support assembly 5 according to the first embodiment, will be described. FIG. 6 is a result of simulation for the consumed edge ring 301 in which the temperature of the dielectric member 510 was set to 80° C. and in which the relative permittivity of the dielectric member 510 was 8. As the permittivity of the dielectric member 510 rises, the electric field distribution in the region B above the edge ring 301 is shifted in a direction away from the base 100. As the electric field distribution shifts away from the base 100, the incident angle of ions at the edge region the substrate W becomes perpendicular to the substrate W, as indicated by the arrow D3 in FIG. 6. Accordingly, even at the end region of the substrate W, etching is performed perpendicular to the substrate W. Therefore, changes in etching profile at the edge region of the substrate W can be suppressed, and thus variations in quality between the central region of the substrate W and the edge region of the substrate W can be suppressed.

### <Control of Permittivity Adjuster 500>

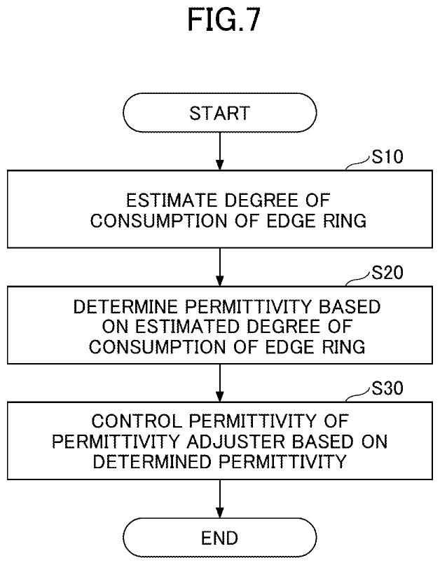

Next, a method for controlling the permittivity adjuster 500 by the controller 400, in a substrate processing method using the substrate processing apparatus 1, will be described. FIG. 7 is a flowchart of a permittivity adjustment process in the substrate processing apparatus 1 according to the first embodiment. The permittivity adjustment process may be performed at any time. For example, the permittivity adjustment process may be performed after processing a predetermined number of the substrates W or a predetermined number of lots and before starting processing for the next substrate W. The permittivity adjustment process may also be performed at the time of resuming substrate processing after maintenance or the like.

### (Step S10)

When the controller 400 of the substrate processing apparatus 1 starts the permittivity adjustment process, the controller 400 estimates the degree of consumption of the edge ring 300. For example, the controller 400 may estimate the degree of consumption of the edge ring 300 from the change in dimension of the edge ring 300, by measuring the change in dimension of the edge ring 300 using an optical technique. Alternatively, the controller 400 may estimate the degree of consumption of the edge ring 300 from the accumulated time of substrate processing that is obtained by accumulating the processing time during which substrate processing using the edge ring 300 has been performed. In particular, the degree of consumption of the edge ring 300 may be estimated from accumulated time obtained by accumulating a length of time during which radio frequency power has been supplied. Further, the controller 400 may estimate the degree of consumption of the edge ring 300 based on the number of substrates or the number of lots processed using the edge ring 300.

### (Step S20)

Next, the controller 400 determines the permittivity to be set to the permittivity adjuster 500, based on the degree of consumption of the edge ring 300 estimated in step S10. For example, by storing, in the storage device or the like in advance, mapping information representing the relationship between a degree of consumption of the edge ring 300 and the optimal permittivity to be set to the permittivity adjuster 500 corresponding to the degree of consumption of the edge ring 300, the controller 400 may determine the permittivity to be set to the permittivity adjuster 500 by using the mapping information. Note that the relationship between a degree of consumption of the edge ring 300 and the optimal permittivity to be set to the permittivity adjuster 500 corresponding to the degree of consumption of the edge ring 300 may be determined in advance by conducting tests and the like.

### (Step S30)

Next, the controller 400 controls the permittivity of the permittivity adjuster 500 based on the permittivity determined in step S20. Specifically, the controller 400 controls the temperature control member 520 such that the permittivity of the dielectric member 510 becomes the permittivity determined in step S20. For example, the controller 400 may determine the temperature to be set to the temperature control member 520 using correlation information between the temperature of the dielectric member 510 and the relative permittivity, as illustrated in, for example, FIG. 3. The controller 400 may control the temperature control member 520 such that the temperature control member 520 becomes the temperature determined by using the correlation information. The correlation information between the temperature of the dielectric member 510 and the relative permittivity may be stored in the storage device or the like in advance.

A set of step S20 and step S30 is an example of a process of adjusting the temperature of the temperature control member in accordance with the degree of consumption of the edge ring.

By performing substrate processing while using the above-described control method, it is possible to reduce the influence of consumption of the edge ring 300 in the substrate processing apparatus 1 according to the first embodiment.

### <Working Effect>

According to the substrate support assembly 5 in the first embodiment, it is possible to reduce the influence of consumption of the edge ring 300. The substrate support assembly 5 according to the first embodiment includes the permittivity adjuster 500, and by adjusting the permittivity of the dielectric member 510, the incident angle of ions at the edge region of the substrate W can be adjusted. By adjusting the incident angle of ions, the influence of consumption of the edge ring 300 can be reduced. Further, because the edge ring 300 and the permittivity adjuster 500 are disposed apart from each other, heat transfer between the edge ring 300 and the permittivity adjuster 500 can be reduced, thereby suppressing the influence on the substrate processing.

In addition, because the influence of consumption of the edge ring 300 is reduced, the edge ring 300 can be used for a long period of time. Thus, the replacement cycle of the edge ring 300 can be extended. As the replacement of the edge ring is time consuming and laborious, the operating time of the substrate processing apparatus can be increased by extending the replacement cycle of the edge ring 300. Also, the maintenance cost of the entire substrate processing apparatus can be reduced.

### Second Embodiment

Next, a substrate processing apparatus according to a second embodiment will be described. The substrate processing apparatus according to the second embodiment and the substrate processing apparatus 1 according to the first embodiment differ in the position where the permittivity adjuster 500 is disposed.

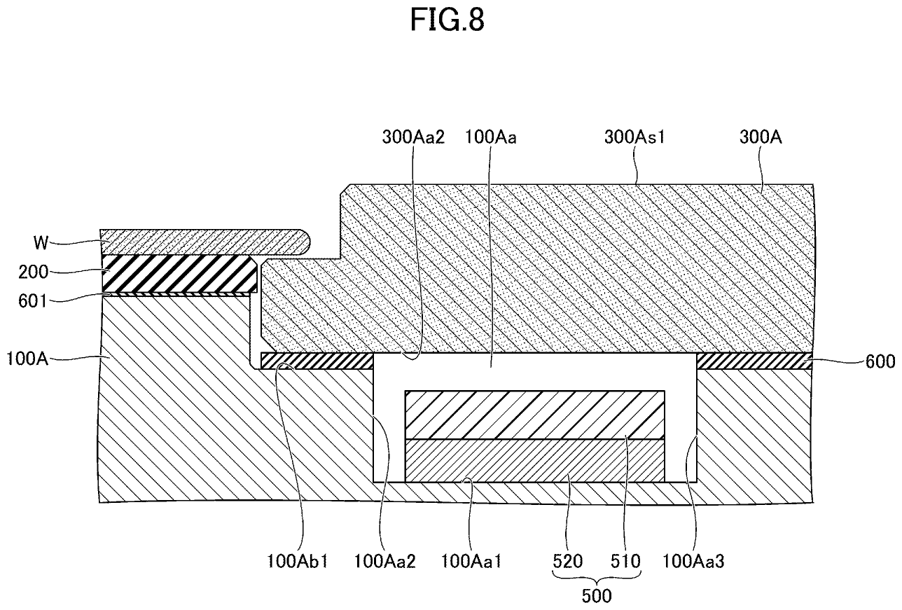

FIG. 8 is an enlarged cross-sectional view illustrating the vicinity of an edge ring 300A for the substrate processing apparatus according to the second embodiment. In the substrate processing apparatus according to the second embodiment, a recess 100Aa for accommodating the permittivity adjuster 500 is formed in the edge ring mounting surface 100Ab1 of a base 100A. The recess 100Aa is an example of a second recess.

The edge ring 300A has a top surface 300As1 exposed to plasma and a bottom surface 300s2 mounted on the edge ring mounting surface 100Ab1, which is on the opposite side of the edge ring 300A with respect to the top surface 300As1. The edge ring 300A is secured to the edge ring mounting surface 100Ab1 via the adhesive layer 600.

The recess 100Aa is of an annular shape when viewed from above. The recess 100Aa has a bottom surface 100Aa1 positioned on the side opposite the bottom surface 300As2 of the edge ring 300A with respect to the recess 100Aa. The recess 100Aa also includes two side surfaces, i.e., a side surface 100Aa2 and a side surface 100Aa3. The side surface 100Aa2 is positioned closer to the side of the substrate W, and the side surface 100Aa3 is on the side opposite the side surface 100Aa2 with respect to the recess 100Aa.

The permittivity adjuster 500 is provided in the recess 100Aa spaced apart from the edge ring 300A, so as not to contact the edge ring 300A. The permittivity adjuster 500 is of an annular shape when viewed from above.

The substrate processing apparatus according to the second embodiment can reduce the influence of consumption of the edge ring while suppressing the influence on substrate processing. Further, a conventional edge ring 300A not having a recess 300a can be used to reduce the influence of consumption of the edge ring 300A.

As the edge ring to be mounted on the base 100A according to the second embodiment, an edge ring including a recess (e.g., edge ring 300 having the recess 300a as described in the first embodiment) may be used. In such a case, the depth of the recess 300a may be changed as appropriate.

### Third Embodiment

Next, a substrate processing apparatus according to a third embodiment will be described. The substrate processing apparatus according to the third embodiment differs from the substrate processing apparatus according to the first and second embodiments in that flow passages 112B are provided in the substrate processing apparatus according to the third embodiment.

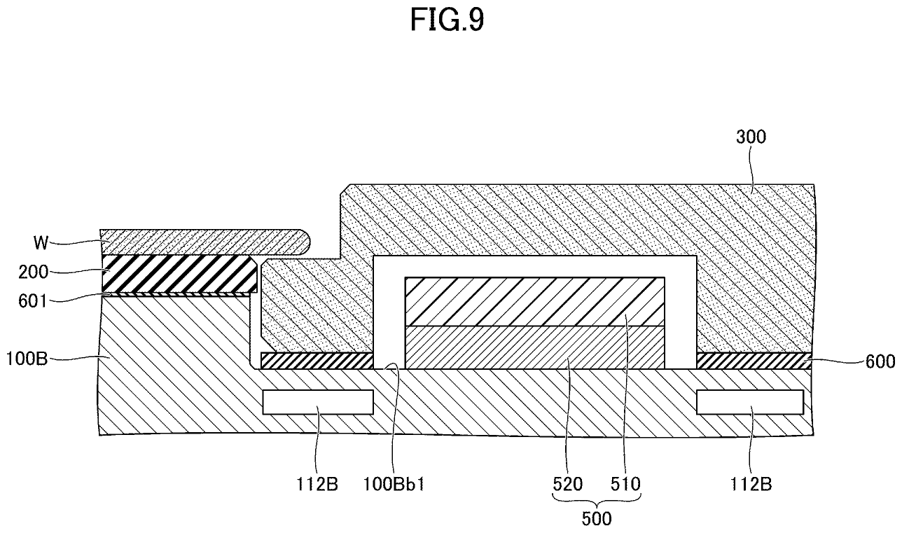

FIG. 9 is an enlarged cross-sectional view illustrating the vicinity of the edge ring 300 for the substrate processing apparatus according to the third embodiment. In FIG. 9, as in other embodiments, the edge ring 300 is secured to an edge ring mounting surface 100Bb1 via an adhesive layer 600. Alternatively, the edge ring 300 may be secured to the edge ring mounting surface 100Bb1 via a heat transfer sheet instead of the adhesive layer 600. The substrate processing apparatus according to the third embodiment includes the flow passages 112B within a base 100B. The flow passages 112B are passages through which a temperature-controlled refrigerant flows. The flow passages 112B are provided under a portion of the edge ring mounting surface 100Bb1, on which the edge ring 300 is mounted. By providing the flow passage 112B, the temperature of the edge ring 300 can be more stably maintained at a desired temperature.

The substrate processing apparatus according to the third embodiment can reduce the influence of consumption of the edge ring 300 while suppressing the influence on substrate processing. In addition, the temperature of the edge ring 300 can be controlled more stably. By stabilizing the temperature of the edge ring 300, the substrate processing characteristics can become more stable. The flow passage 112B is an example of the temperature control medium flow passage.

### <<Variations>>

The substrate processing apparatus according to the embodiments disclosed herein should be considered to be an example in all respects and not restrictive. The above embodiments may be modified and enhanced in various forms without departing from the appended claims and spirit thereof. Matters described in the above embodiments may take on other configurations insofar as there are no contradictions, and may be combined insofar as there are no contradictions.

The permittivity adjuster 500 according to the above-described embodiments is provided apart from the edge ring, but a heat insulating member may be provided between the permittivity adjuster and the edge ring.

The temperature control member 520 according to the above-described embodiments employs an electric heater, but the temperature control member is not limited to an electric heater. For example, an infrared heater may be employed, or a heat transfer medium may be used to adjust the temperature.

In the above-described embodiments, the recess 300a, the recess 100Aa, and the permittivity adjuster 500 are annular. However, in another embodiment, multiple recesses and multiple permittivity adjusters may be provided spaced apart.

The edge ring according to the above-described embodiments is secured to the base 100 via the adhesive layer 600 or the heat transfer sheet, but an electrostatic chuck may be used to mount the edge ring. The electrostatic chuck for the edge ring may be integral with or separate from an electrostatic chuck for a substrate W. An electrode for the electrostatic chuck for the edge ring may be monopolar or bipolar electrodes. In a case in which the bipolar electrodes are employed, the edge ring can be attracted even while no plasma is generated. Additionally, in a case in which the edge ring is attracted by the electrostatic chuck, a heat transfer gas may be supplied to a space between the edge ring and the electrostatic chuck.

The substrate processing apparatus of the present disclosure is applicable to any type of device such as a capacitively coupled plasma (CCP) type processing apparatus, an inductively coupled plasma (ICP) type processing apparatus, and an apparatus for generating a plasma using a microwave, such as a plasma using a radial line slot antenna (RLSA), an electron cyclotron resonance plasma (ECR), and a helicon wave plasma (HWP).

What is claimed is:

1. A substrate support assembly comprising:
a substrate mounting section on which a substrate is to be placed;
an edge ring mounting section;
an edge ring mounted on the edge ring mounting section so as to surround the substrate;
a dielectric member provided under the edge ring, a permittivity of the dielectric member being temperature dependent; and
a temperature control member configured to adjust a temperature of the dielectric member; wherein
the dielectric member and the temperature control member are disposed apart from the edge ring.

2. The substrate support assembly according to claim 1, wherein the dielectric member is disposed on a top surface of the temperature control member.

3. The substrate support assembly according to claim 1, wherein a first recess is provided in a bottom surface of the edge ring, the first recess accommodating the dielectric member and the temperature control member.

4. The substrate support assembly according to claim 1, wherein the edge ring mounting section includes a second recess that accommodates the dielectric member and the temperature control member.

5. The substrate support assembly according to claim 1, wherein
a temperature control medium flow passage is provided in the edge ring mounting section, under a mounting surface of the edge ring mounting section on which the edge ring is mounted; and
the temperature control medium flow passage is configured to adjust a temperature of the edge ring.

6. The substrate support assembly according to claim 1, wherein the dielectric member is formed of polyamide, polyacetal, or a combination of polyamide and polyacetal.

7. The substrate support assembly according to claim 2, wherein a first recess is provided in a bottom surface of the edge ring for accommodating the dielectric member and the temperature control member.

8. The substrate support assembly according to claim 7, wherein the edge ring mounting section includes a second recess that accommodates the dielectric member and the temperature control member.

9. The substrate support assembly according to claim 8, wherein
a temperature control medium flow passage is provided in the edge ring mounting section, under a mounting surface of the edge ring mounting section on which the edge ring is mounted; and
the temperature control medium flow passage is configured to adjust a temperature of the edge ring.

10. The substrate support assembly according to claim 9, wherein the dielectric member is formed of polyamide, polyacetal, or a combination of polyamide and polyacetal.

11. A substrate processing apparatus comprising:
a processing vessel including a gas supply port and a gas exhaust port;
the substrate support assembly according to claim 1, the substrate support assembly being disposed in the processing vessel;
a radio frequency power supply configured to generate a plasma; and
a controller.

12. A method of processing a substrate performed by the substrate processing apparatus according to claim 11, the method comprising:
processing the substrate; and
controlling a temperature of the dielectric member by using the temperature control member in accordance with a degree of consumption of the edge ring.
